(19) United States
(12) Patent Application Publication
(10) Pub. No.: US 2013/0021037 A1
(43) Pub. Date: Jan. 24, 2013

(54) WIRELESS PORTABLE BATTERY CAPACITY TEST SYSTEM

(71) Applicants: Edward W. Deveau, Pompano Beach, FL (US); Jeffrey Alber, Boca Raton, FL (US)

(72) Inventors: Edward W. Deveau, Pompano Beach, FL (US); Jeffrey Alber, Boca Raton, FL (US)

(73) Assignee: Liebert Corporation, Columbus, OH (US)

(21) Appl. No.: 13/354,367

(22) Filed: Jan. 20, 2012

Related U.S. Application Data
(60) Provisional application No. 61/434,940, filed on Jan. 21, 2011.

(51) Int. Cl. G01R 31/36

(52) U.S. Cl. 324/427

(57) ABSTRACT

A battery capacity test system includes one or more wireless battery capacity test (“BCT”) sense modules, a continuous load unit, and a wireless data collection unit. The wireless data collection unit interfaces with a computer. During a battery capacity test, the wireless BCT sense module (or modules) continuously monitors the voltage of the battery cell (or cells) to which it is connected. In an aspect, it also continuously monitors the temperature of the battery cell (or cells) and intercell voltage (or voltages) across an intercell connector (or connectors). Each wireless BCT sense module wirelessly transmits the voltage and temperature data it collects to the wireless data collection unit.

### CROSS-REFERENCE TO RELATED APPLICATIONS

This application claims the benefit of U.S. Provisional Application No. 61/434,940, filed on Jan. 21, 2011. The entire disclosure of the above application is incorporated herein by reference.

### FIELD

The present disclosure relates to battery test systems and more particularly, to a wireless portable battery capacity test system.

### BACKGROUND

This section provides background information related to the present disclosure which is not necessarily prior art.

Uninterruptible power supply systems, such as those used for data centers, often utilize batteries as the source of back-up power. Each battery typically has multiple cells or multicell modules connected in series to provide the requisite voltage, commonly referred to as a battery string. The term “cell” or “battery cell” will be used herein to refer to both individual cells and multicell modules (sometimes term “monoblocs”) of a battery string unless the context dictates otherwise. The individual battery cells adjacent to each other in a section of a battery string are connected to each other by a conductive connector, such as a copper bus bar, strap, cable or the like. This connector is commonly referred to as an intercell or intercell connector. Adjacent sections of a battery string are connected to each other by a longer conductive connector, such as a cable or group of cables (that are longer than cables used for intercell connectors), referred to as an intertier or intertier connector.

Since a battery has a finite life, it will eventually fail. Consequently, battery monitors are often used to monitor the batteries in UPS systems. By detecting battery problems at an early stage before they can cause abrupt system failure, system reliability is improved.

Currently, battery capacity testing is the best known method for determining capacity of a battery system in spite of all the other claims made within the industry. Other methods such as internal impedance, conductance or resistance can only ascertain if the battery system will function under load but cannot give an actual capacity value or tell you how long the battery system will run under load. Capacity testing is periodically performed based on the type of battery cells used in the battery system and past test results. Test intervals can range from months to many years and therefore the equipment needs to be portable and only installed at time of testing. The only exception to this is if the battery system has a stationary battery monitor, it is feasible to have this feature built into the battery monitor.

A battery capacity test system is a device used in the maintenance and testing of battery systems. It can perform three commonly used tests: acceptance, capacity and critical period testing. Acceptance testing is the applying and control of a constant current or power to a specified end voltage to determine if the battery system meets design criteria's. Capacity testing is also the applying and control of a constant current or power to an end voltage to determine actual battery capacity. Critical period testing is the applying and control of a load in the portion of a duty cycle that is most severe to a battery system and also commonly referred to as performance testing. IEEE standard 450 or 1188 describe variations in test and methods for determining capacity.

One such battery capacity test system is the Alber BCT-2000 Series of battery capacity test system available from Alber Corporation of Pompano Beach, Fla.

Although voltage and current are the only parameters required to measure capacity, there are other parameters that can be acquired to help mitigate dangerous operating conditions or further damage to the battery system being tested. Premature failure of battery cells under a high current discharge rates could result in further damage resulting in fire or explosion. Monitoring other metrics such a negative post temperature and intercell voltages can help identify these conditions before they can accelerate to harmful or destructive situations.

Monitoring the post temperature of a battery cell is an acceptable method for identifying internal battery cell temperatures and can give an early warning of a high resistance connection within the battery cell. Temperatures on defective battery cells can rise to extreme levels under the right conditions and by monitoring these during the loading process they can be identified and early termination (removal of the load) of the test can be achieved.

Measuring the voltage drop across the intercell connector (connection between battery cells) can identify a bad connection resulting again in a high temperature condition that could result in further damage and possible fire if not caught in time. Normal testing practice could incorporate a pretest that subjects the battery to a much lower current that would allow the system to identify any faulty connections. This process will not subject the system to a destructive situation by applying a high rate current immediately.

Battery monitors may for example utilize the teachings of U.S. Pat. No. 4,707,795 for “Battery Testing and Monitoring System” issued Nov. 17, 1987 and/or U.S. Pub. No. 2009/0224771 for “System and method for Measuring Battery Internal Resistance,” published Sep. 10, 2009, the entire disclosures of which are incorporated herein by reference.

Performing capacity testing on stationary battery systems is a labor intensive job. This test is performed periodically to identify the actual capacity of a battery system. It typically involves using large quantities of connection wire in order to connect each battery cell in the battery strings of the battery systems back to the acquisition equipment. A typical length of connection wire used with battery capacity test systems is approximately fifty feet per battery cell in order to accommodate variations in the battery systems encountered in the field. Large count battery strings may have 240 battery cells per battery string, thus requiring the installation and management of approximately 12,000 feet of connection wire. Not only does this present a difficult task in keeping the connection wires organized and untangled, but also can present reliability concerns. Reliability can be reduced due to the number of series connections needed for each sense. Each lead includes six connections from the acquisition equipment to the battery cell. When considering the example of a battery string having 240 battery cells, this involves over 1,400 connections. The leads, since a portion of them typically lay on the floor of the facility as they run from the acquisition equipment to the battery cells, may be stepped on by personnel conducting the tests, stressing and possibly pulling the lead from the battery cell connection or acquisition equipment.

Another concern is the expense of moving the battery capacity test equipment from one location to another. Since the amount of connection wire needed is large and is also heavy, it may need to be shipped from one location to another by truck or air freight, adding addition cost to the testing process.

Yet another concern is that in typical portable battery capacity test systems, the data acquisition equipment is a single unit and if it fails, the entire system must be returned for repair.

### SUMMARY

This section provides a general summary of the disclosure, and is not a comprehensive disclosure of its full scope or all of its features.

In accordance with an aspect of the present disclosure, a battery capacity test system includes one or more wireless battery capacity test (“BCT”) sense modules, a continuous load unit, and a wireless data collection unit that communicates wirelessly with the wireless BCT sense modules. The wireless data collection unit interfaces with a computer, which may be a laptop computer.

In an aspect of the present disclosure, at least one wireless BCT sense module is connected to the battery cells of the battery string being tested. During the test, the wireless BCT sense module continuously monitors the voltage of the battery cell to which it is coupled to collect data. In an aspect, it also continuously monitors the temperature of the battery cell to which it is coupled and an intercell voltage across an intercell connector connecting a positive post of the battery cell to a negative post of an adjacent battery cell. If the wireless BCT sense module is coupled to more than one of the battery cells, it monitors this data for each of the battery cells to which it is coupled. The wireless BCT sense module wirelessly transmits the data it collects to the wireless data collection unit. The wireless data collection unit collects the data transmitted from the wireless BCT sense module, buffers it, and communicates the buffered data to the computer. The computer, which is coupled to the continuous load unit, controls the continuous load unit to maintain a constant current or power load on the battery string being tested using the parameters for the particular test being conducted, the data provided by the wireless BCT sense modules, and the load current read from the continuous load unit.

In an aspect, the system has a wireless BCT sense module for each battery cell and the BCT sense modules are coupled to respective ones of the battery cells.

In an aspect, an individual wireless BCT sense module is coupled to a plurality of the battery cells, monitors those battery cells to collect data, and wireless transmits the collected data to the wireless data collection unit.

Further areas of applicability will become apparent from the description provided herein. The description and specific examples in this summary are intended for purposes of illustration only and are not intended to limit the scope of the present disclosure.

The drawings described herein are for illustrative purposes only of selected embodiments and not all possible implementations, and are not intended to limit the scope of the present disclosure.

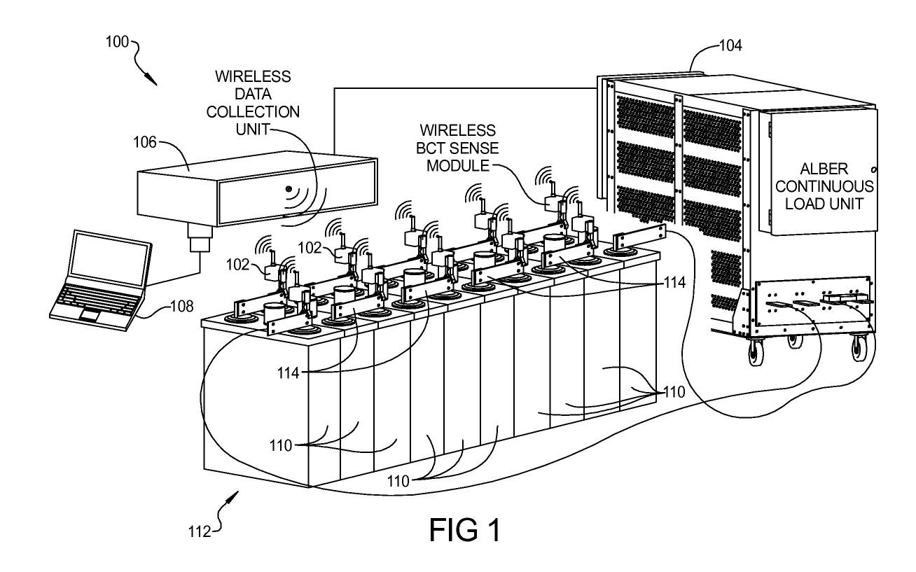

FIG. 1 is a simple schematic view of a wireless battery capacity test system in accordance with an aspect of the present disclosure;

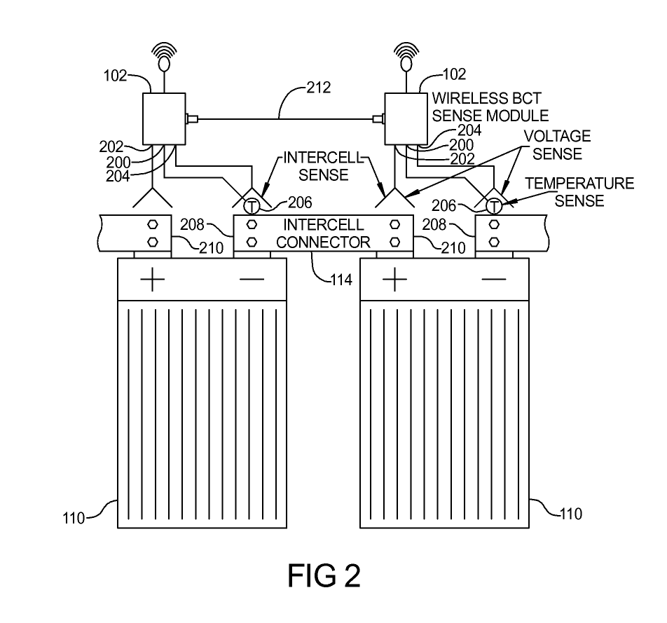

FIG. 2 is a simple schematic view showing the connection of wireless battery capacity sense modules of FIG. 1 to battery cells of a battery string being tested by the test system of FIG. 1;

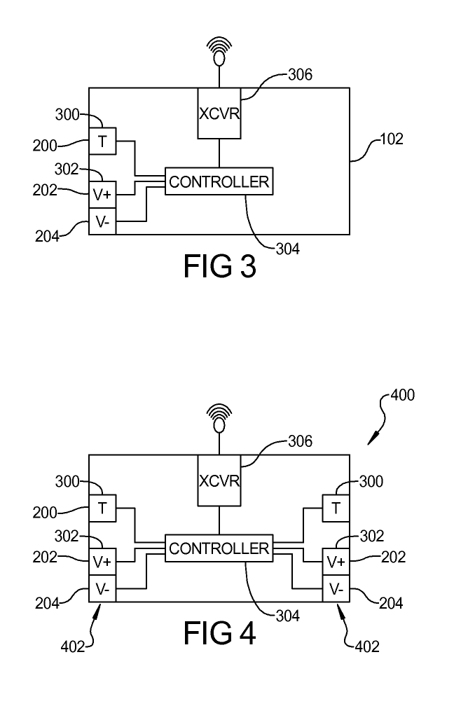

FIG. 3 is a basic block diagram of a wireless battery capacity sense module of the test system of FIG. 1; and

FIG. 4 is a basic block diagram of a variation of the wireless battery capacity sense module of FIG. 3.

Corresponding reference numerals indicate corresponding parts throughout the several views of the drawings.

### DETAILED DESCRIPTION

Example embodiments will now be described more fully with reference to the accompanying drawings.

With reference to FIG. 1, in accordance with an aspect of the present disclosure, a battery capacity test system 100 includes a plurality of wireless battery capacity test (“BCT”) sense modules 102, a continuous load unit 104 and a wireless data collection unit 106. Wireless data collection unit 106 interfaces with a computer 108, which may illustratively be a laptop computer. In the embodiment shown, a USB cable connects wireless data collection unit 106 to computer 108. It should be understood that wireless data collection unit could interface to computer 108 in other known ways, such as wiFI, Bluetooth®, Ethernet®, and the like. Illustratively, there is a wireless BCT sense module for each battery cell 110 in battery string 112 being tested. As discussed above, the term “battery cell” will be used herein to refer to both individual battery cells and monoblocs unless the context dictates otherwise. Adjacent battery cells 110 in battery string 112 are connected by an intercell connector 114.

Continuous load unit 104 may illustratively be a continuous load unit (e.g., any of Models 1N-8NS) available from Alber for the BCT-2000 Series battery capacity test system referenced above in the Background section.

FIG. 2 shows in more detail the connection of wireless BCT sense modules 102 to the battery cells of battery string 112, illustratively shown by two wireless BCT sense modules 102 connected to two battery cells 110. Each wireless BCT sense modules 102 includes a temperature sense input 200 and voltage sense inputs 202, 204. Temperature sense input 200 is coupled to a temperature sensor 206 coupled to a post of battery cell 110, such as to negative post 208 of battery cell 110. One of voltage sense inputs 202, 204 is coupled to the negative post 208 of battery cell 110 and the other voltage sense input 202, 204 is coupled to a positive post 210 of battery cell 110. Wireless BCT sense modules 102 connected to adjacent battery cells 110 are interconnected to each other by an intercell crossover lead 212.

In conducting a battery capacity test, a wireless BCT sense module 102 is connected to each battery cell 110 and continuous load unit 104 is coupled to battery string 112. During the test, each wireless BCT sense module 102 continuously monitors the temperature and voltage of the battery cell 110 to which it is connected. It also continuously monitors the intercell voltage across the intercell connector 114 connecting the positive post 210 of the battery cell 110 to the negative post 208 of the adjacent battery cell 110. Each wireless BCT sense module 102 wirelessly transmits the voltage and temperature data it collects to wireless data collection unit 106. Wireless data collection unit 106 collects the data transmitted from the wireless BCT sense modules 102, buffers it, and communicates the buffered data to computer 108. It should be understood that wireless BCT sense modules 102 could, alternatively, wirelessly transmit data directly to computer 108 in which case computer 108 acts as the wireless data collection unit. In this regard, the term “wireless data collection unit” means any type of device that can communicate wirelessly with BCT sense modules 102, including computers having wireless communication capability, data loggers having wireless communication capability, and the like. Computer 108, which is coupled to continuous load unit 104, controls continuous load unit 104 in known fashion to maintain a constant current or power load on battery string 112 using the parameters for the particular test being conducted, the data provided by the wireless BCT sense modules 102, and the load current read from the continuous load unit 104.

FIG. 3 is a basic block diagram of a wireless BCT sense module 102. Wireless BCT sense module 102 includes a temperature acquisition circuit 300 having temperature sense input 200, voltage acquisition circuit 302 having voltage sense inputs 202, 204, controller 304 and wireless transceiver 306. Temperature acquisition circuit 300 and voltage acquisition circuit 302 are coupled to controller 304. Controller 304 is coupled to wireless transceiver 306. The data acquired by temperature acquisition circuit 300 and voltage acquisition circuit 302 is communicated to controller 304 which transmits it to wireless data collection unit 106 via wireless transceiver 306.

It should be understood that wireless BCT sense module 102 can be used for the more rudimentary type of battery capacity test where the temperatures of the battery cells and the intercell voltages are not monitored. In this type of battery capacity test, during the test the BCT sense module 102 then only monitors the voltage of the battery cell 110 to which it is connected and wirelessly transmits this voltage data to wireless data collection unit 106. In regard, BCT sense module 102 may then be configured without temperature sense input 200.

In a variation, the wireless BCT sense module may be configured to monitor a plurality of battery cells 110. With reference to FIG. 4, a wireless BCT sense module 400 has a plurality of sets 402 of sense inputs, one for each battery cell 110 to which wireless BCT sense module 400 is connected. While two such sets 402 of sense inputs are shown, it should be understood that this is exemplar and wireless BCT sense module 400 would have more than two sets 402 of sense inputs if it is connected to more than two battery cells 110. Each set 402 of sense inputs includes temperature sense input 200 and voltage sense inputs 202, 204. It should be understood that if wireless BCT sense module 400 is used for the more rudimentary type of battery capacity test where it monitors only the voltages of battery cells 110, the sets 402 of sense inputs may not include temperature sense input 200. Wireless BCT sense module 400 also illustratively includes a temperature acquisition circuit 300 for each temperature sense input 200 and a voltage acquisitions circuit 302 for each set of voltage sense inputs 202, 204. Alternatively, there can be one temperature acquisition circuit 300 for the temperature sense inputs 200 (or groups of the temperature sense inputs 200 and a multiplexing arrangement used to couple the temperature sense inputs 200 to the temperature acquisition circuit or circuits 300. A similar multiplexing arrangement can be used for the voltage sense inputs 202, 204 and the voltage acquisition circuit (or circuits) 302.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A battery capacity test system for testing a battery string having a plurality of battery cells wherein adjacent battery cells are connected to each other by an intercell connector, the system comprising:
a continuous load unit for coupling to the battery string and maintaining a constant load on the battery string during a battery capacity test of the battery string;
a wireless data collection unit;
at least one wireless battery capacity test sense module for coupling to the battery cells and that communicates wirelessly with the wireless data collection unit, the wireless battery capacity test sense module having positive and negative voltage sense inputs for coupling to positive and negative posts of the battery cells; and
wherein during the battery capacity test, the wireless battery capacity sense module collects data by continuously monitoring the voltage of each battery cell to which wireless battery capacity sense module is coupled and transmits wirelessly the data it collects to the wireless data collection unit.

2. The system of claim 1 wherein the battery capacity test module includes a plurality of sets of positive and negative voltage sense inputs for coupling to the positive and negative posts of a plurality of the battery cells.

3. The system of claim 1 wherein the battery capacity test sense module includes a voltage acquisition circuit having the positive and negative voltage sense inputs, a wireless transceiver, and a controller coupled to the temperature acquisition circuit, the voltage acquisition circuit and the wireless transceiver.

4. The system of claim 1 wherein the battery capacity sense test module includes a plurality of temperature sense inputs for coupling to one of the positive and negative posts of a plurality of the battery cells and during the battery capacity test the wireless battery capacity sense module also continuously monitors the temperature of the battery cells to which it is coupled to collect battery cell temperature data and continuously monitors intercell voltage across the intercell connectors connecting battery cells to which the battery capacity sense test module is coupled to collect intercell voltage data and includes the temperature data and intercell voltage data in the data that the battery capacity test module wirelessly transmits to the wireless data collection unit.

5. The system of claim 1 including a plurality of the wireless battery capacity sense modules, one for coupling to each battery cell in the battery string.

6. The system of claim 5 wherein when the wireless battery test sense modules are coupled to the battery cells, wireless battery test sense modules coupled to adjacent battery cells of the battery string are interconnected to each other by an intercell crossover lead, the positive and negative voltage sense inputs of each wireless battery capacity sense modules for coupling to the positive and negative posts of respective ones of the battery cells;
each battery capacity sense test module includes a temperature sense input for coupling to one of the positive and negative posts of one of the battery cells and during the battery capacity test the wireless battery capacity sense module also continuously monitors the temperature of the battery cell to which it is coupled to collect battery cell temperature data and continuously monitors intercell voltage across the intercell connector connecting adjacent battery cells to which the battery capacity sense test module is coupled to collect intercell voltage data and includes the temperature data and intercell voltage data in the data that the battery capacity test module wirelessly transmits to the wireless data collection unit.

7. The system of claim 6 wherein each battery capacity test sense module includes a temperature acquisition circuit having the temperature sense input, a voltage acquisition circuit having the positive and negative voltage sense inputs, a wireless transceiver, and a controller coupled to the temperature acquisition circuit, the voltage acquisition circuit and the wireless transceiver.

8. The system of claim 1 including a computer coupled to the continuous load unit and the wireless data collection unit, the wireless data collection unit communicating the data received from the wireless battery capacity test modules to the computer, the computer controlling the continuous load unit to maintain a constant load on the battery string.

9. The system of claim 1 wherein the wireless data collection unit is a computer that is coupled to the continuous load unit, the computer controlling the continuous load unit to maintain a constant load on the battery string.

10. A method of performing a battery capacity test of a battery string having a plurality of battery cells wherein adjacent battery cells are connected to each other by an intercell connector, comprising:
coupling at least one wireless battery capacity test sense module to the battery cells by coupling positive and negative posts of the battery cells to positive and negative voltage sense inputs of that wireless battery capacity test sense module;
applying during the battery capacity test a continuous load to the battery string with a continuous load unit coupled to the battery string;
continuously monitoring with the wireless battery capacity test modules connected to the battery cells the voltages of the battery cells to collect data; and
wirelessly transmitting with the wireless battery capacity test module the data to a wireless data collection unit.

11. The method of claim 10 wherein the wireless battery capacity test sense module includes a plurality of sets of positive and negative voltage sense inputs and coupling the positive and negative posts of the battery cells to positive and negative voltage sense inputs of that wireless battery capacity test sense module includes coupling the positive and negative posts of respective ones of the battery cells to respective sets of the positive and negative voltage sense inputs.

12. The method of claim 11 wherein the battery capacity sense test module includes a plurality of temperature sense inputs, the method further including coupling the temperature sense inputs to one of the positive and negative posts of respective ones of a plurality of the battery cells, and during the battery capacity test also continuously monitoring with the battery capacity sense test module the temperature of the battery cells to which the battery capacity sense test module is coupled it to collect battery cell temperature data and continuously monitoring intercell voltage across the intercell connectors connecting battery cells to which the battery capacity sense test module is coupled to collect intercell voltage data and including the temperature data and intercell voltage data in the data collected by the battery capacity sense test module and wirelessly transmitted to the wireless data collection unit.

13. The method of claim 10 including a plurality of the wireless battery capacity sense modules, once for each battery cell and coupling the positive and negative sense inputs of each wireless battery capacity sense module to the positive and negative posts of a respective one of the battery cells.

14. The method of claim 13 including interconnecting with an intercell crossover leads wireless battery capacity test modules connected to adjacent battery cells, coupling a temperature sense input of each wireless battery capacity test module to the positive or negative positive of a respective one of the battery cells, also continuously monitoring with the wireless battery capacity test modules the temperature of the battery cells and the intercell voltages across the intercell connectors to collect battery cell temperature data and intercell voltage data and including the collected temperature data and intercell voltage data in the data that the battery capacity test module wirelessly transmits to the wireless data collection unit.

15. The method of claim 10 wherein wirelessly transmitting the data to a wireless data collection unit includes transmitting the data to a computer that is also coupled to the constant load unit and controlling the continuous load unit with the computer to maintain a constant load on the battery string.
